(19) United States
(12) Patent Application Publication
(10) Pub. No.: US 2010/0286936 A1
(43) Pub. Date: Nov. 11, 2010

(54) METHOD FOR DETERMINING AND ASSEMBLING CHARACTERISTIC VARIABLES OF AN ELECTRICAL POWER SUPPLY

(76) Inventor: Rainer HAUSER, Nurnberg (DE)

Correspondence Address: HARNESS, DICKEY & PIERCE, P.L.C., P.O.BOX 8910, RESTON, VA, 20195, US

(21) Appl. No.: 12/770,835

(22) Filed: Apr. 30, 2010

(30) Foreign Application Priority Data
May 6, 2009 (DE) 10 2009 020 151.3

(51) Int. Cl. G01R 31/40; G06F 19/00

(52) U.S. Cl. 702/60

(57) ABSTRACT

A method is disclosed for determining and assessing characteristic variables of an electrical power supply, in which the assessing operation includes violating predefined limit values, and in which the same binary value is respectively assigned to a violation. In order to make it possible to parameterize limit value combinations in a user-friendly manner, it is proposed in at least one embodiment that a plurality of function blocks be provided; each of which has a plurality of inputs and an output; the applied binary signals being combined with one another according to a logic function; he result being available as a binary signal at the output; at least the binary output signal from a function block be switched to the input of another function block; the limit value applied to the respective input as well as the logic function of the function block itself for parameterizing the assessment be able to be selected from a predefined number of limit values and logic functions; and a total binary signal be generated in order to indicate, in particular to an operator or a further processing system, that characteristic variables have been violated.

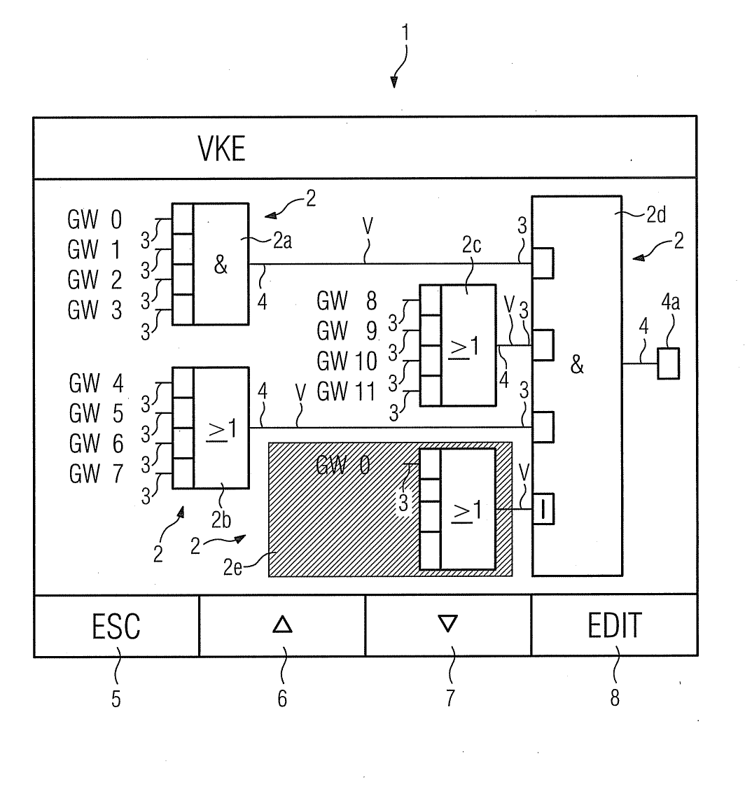

### PRIORITY STATEMENT

The present application hereby claims priority under 35 U.S.C. §119 on German patent application number DE 10 2009 020 151.3 filed May 6, 2009, the entire contents of which are hereby incorporated herein by reference.

### FIELD

At least one embodiment of the invention generally relates to a method for determining and assessing characteristic variables of an electrical power supply.

### BACKGROUND

Devices for electrical power supplies, in particular electricity supply systems, which are used to determine and assess characteristic variables are known as PMDs (Power Monitoring Devices). In this case, the characteristic variables may be measured values determined by the PMDs as well as variables derived from the measured values. The characteristic variables are assessed using a violation of predefined limit values, limit values also being understood as meaning limit value conditions. For the purpose of assessment, one binary value of a binary signal, for example a logic one, is respectively assigned to a violation and the respective other binary value of this signal, for example a logic zero, is assigned to a non-violation.

Furthermore, the binary values are logically combined with one another in order to use them to generate a total binary value (a total signal) which indicates to an operator that characteristic variables have been violated and thus leads to protective measures being initiated. This total binary value in the, form of a logic one or zero can also be used for further processing by machine. The binary values are nowadays combined by means of textual parameterization and programming in a suitable language. The disadvantage is that many logic combinations can be executed only to a limited extent on account of missing bracketing levels. Meaningful combinations are restricted to “all” or at least “one”.

### SUMMARY

At least one embodiment of the invention makes it possible to parameterize limit value combinations in a user-friendly manner.

The solution, in at least one embodiment, provides for a plurality of function blocks to be provided, each of which has a plurality of inputs and an output, the binary signals of at least two limit values respectively being applied to an input of a function block, the applied binary signals being combined with one another according to a logic function assigned to the function block, and the result of the combination likewise respectively being available as a binary signal, in particular as a logic one or zero, at the output, for at least the binary output signal from a function block to be switched to the input of another function block, for the limit value applied to the respective input as well as the logic function of the function block itself for parameterizing the assessment to be able to be selected from a predefined number of limit values and logic functions, and for a total binary signal to be generated in order to indicate, in particular to an operator or a further processing system, that characteristic variables have been violated (and in order to initiate corresponding protective measures). The use of function blocks makes it possible to combine selected limit values with one another with regard to their violation via a function block by means of the same logic function, that is to say by means of the function “AND”, “NAND”, “OR”, “NOR” etc. In this case, each function block may have a predefined number of inputs, for example four inputs. A limit value can be assigned to each of these inputs by means of selection from a list (for example a pull-down menu). An assessment is processed function block by function block, which corresponds to bracketing, that is to say also allows a bracketing level.

A particularly simple embodiment provides for the function blocks with their inputs to be presented on a display in a permanently predefined arrangement and combination. The parameterization in the interaction with the permanent arrangement structure and function blocks is user-friendly and can also be effected on a relatively small display.

The result of the assessment is expediently effected by way of an output function block which emits a total binary signal.

The overview of the assessment can be improved if each violation is indicated at the corresponding input of the function blocks.

The method, in at least one embodiment, can be extended beyond the pure assessment of characteristic variables if further digital signals, in particular the switching state of a switch, can also be applied, in addition to limit values, to the inputs as a binary signal.

For the purpose of simplification, it is proposed that at least one output of a function block be able to be parameterized as an inverting output.

### BRIEF DESCRIPTION OF THE DRAWINGS

The invention is described in more detail below using an example embodiment.

The single FIGURE of the drawing shows a display 1 of a PMD (Power Monitoring Device).

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

The PMD is used to determine and assess characteristic variables of an electrical power supply (not shown any further), the measured values of the electrical power supply which are determined by the PMD themselves being able to act as characteristic variables. However, the characteristic variables are generally derived from the measured values determined.

The display 1 has a plurality of function blocks 2 in a permanent arrangement and with a permanently predefined combination V of the function blocks 2. Each function block 2 has a plurality of inputs 3 and one output 4. Limit values GW (GW1 to GW11) are applied to the inputs 3 in the form of binary signals. Each binary signal comprises two binary values which are assigned a logic one and a logic zero (one binary value thus respectively corresponds to a logic one and the other value respectively corresponds to a logic zero). If, for a limit value GW, a logic one is applied to the input of a function block 2, this means that this limit value has been violated. A logic zero consequently corresponds to a non-violation of the associated limit value GW. In this case, a limit value can also be understood as meaning a limit value condition.

In the FIGURE, each function block 2 has four limit value inputs 3, only one limit value, the limit value GW0, being applied to the function block 2e for example. Each function block 2 is assigned a logic function (“AND”, “NAND”, “OR”, “NOR” etc.) which is used to logically combine the binary signals applied to the inputs 3. The function block 2a is thus assigned the logic function “AND” (indicated as “&”), which corresponds to the following logic combination: “GW0 AND GW1 AND GW2 AND GW3”. In the function blocks 2b, 2c, 2e, a check is carried out in order to determine whether one of the limit values applied to the inputs is GW>=1. If this is the case, a corresponding binary signal, logic one in this case, is output at the outputs 4 of the function blocks 2b, 2c, 2e as the result of the assessment. The binary signals of the outputs 4 are all passed to an output function block 2d which combines them by means of an “&” function. The output function block 2d uses this to generate a total binary signal 4a which can be displayed to an operator, for example, in order to initiate corresponding protective measures. However, it is also possible to process this total signal 4a further by machine. If the total signal 4a indicates a violation, this is displayed in a stylized manner as “1” on the display.

For the purpose of parameterization, four fields 5, 6, 7, 8, which are denoted ESC (field 5), “up arrow” (field 6), “down arrow” (field 7) and EDIT (field 8) in the FIGURE, are provided on the lower edge. The fields 5 can be activated by touch if the display is in the form of a touch-screen. However, it is also possible for the fields 5 to be in the form of buttons.

Parameterization is started by activating the field 8 (EDIT), as a result of which a function block is marked. The function block 2e is shown as marked in the FIGURE. The arrow fields 6, 7 can be used to change from one function block 2 to another, that is to say from the function block 2e to the function block 2d and so on. Further activation of the field 8 (EDIT) means that the limit values GW can be set for the respectively marked function block 2e, the arrow fields 6, 7 being used to first of all select the corresponding input. The limit value GW can then be selected for the selected input by activating the EDIT field 8 again, all limit values GW appearing in a pull-down menu, from which the desired limit value GW is selected, again using the arrow fields 6, 7 and then the EDIT field 8. Further activation of the EDIT field 8 results in the logic function of the function block 2 being parameterized, the individual logic functions appearing in the function block in succession by activating the arrow fields 6, 7. Further activation of the EDIT field 8 in turn records the logic function (assigns the displayed logic function to the function block 2). The ESC field 5 can be used to move back again in stages (in levels) and thus to cancel the last EDIT activation. A changeover is made to the next function block 2 and so on in a corresponding manner.

As the FIGURE shows, individual inputs, the input 3a in this case, are provided with a stylized “1”, which means a logic one and thus corresponds to a violation. In the FIGURE, the function block 2e signals a violation and, since only one limit value, namely GW0, is applied, signals the violation of the limit value GW0 in terms of the limit value condition >=1. The limit value GW3 (function block 2a) has likewise been violated.

Furthermore, in addition to limit values, digital signals can also be connected to the inputs 3 of the function blocks instead of limit values, for example the switching state of a switch, logic one corresponding to the switching state “switched on” and logic zero corresponding to the switching state “switched off”.

Each output can be parameterized as an inverting output, which is again effected by activating the EDIT field 8.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combineable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, computer readable medium and computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a computer readable medium and is adapted to perform any one of the aforementioned methods when run on a computer device (a device including a processor). Thus, the storage medium or computer readable medium, is adapted to store information and is adapted to interact with a data processing facility or computer device to execute the program of any of the above mentioned embodiments and/or to perform the method of any of the above mentioned embodiments.

The computer readable medium or storage medium may be a built-in medium installed inside a computer device main body or a removable medium arranged so that it can be separated from the computer device main body. Examples of the built-in medium include, but are not limited to, rewriteable non-volatile memories, such as ROMs and flash memories, and hard disks. Examples of the removable medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A method for determining and assessing characteristic variables of an electrical power supply, in which the assessing of the characteristic variables includes violating predefined limit values in which a same binary value of a binary signal is respectively assigned to a violation and another binary value of this binary signal is respectively assigned to a non-violation, the method comprising:
providing a plurality of function blocks, each including a plurality of inputs and an output;
applying the binary signals of at least two limit values, respectively, to an input of one of the plurality of function blocks;
combining the applied binary signals with one another according to a logic function assigned to the function block, a result of the combination respectively being available as a binary signal at the output;
switching at least the binary output signal from a function block to the input of another function block, a limit value applied to the respective input and the logic function of the function block itself for parameterizing the assessment being selectable from a predefined number of limit values and logic functions; and
generating a total binary signal in order to indicate that characteristic variables have been violated.

2. The method as claimed in claim 1, wherein the plurality of function blocks with their inputs are presented on a display in a permanently predefined arrangement and combination.

3. The method as claimed in claim 1, wherein an output function block generates the total binary signal.

4. The method as claimed in claim 1, wherein each violation is indicated at the corresponding input of the function blocks.

5. The method as claimed in claim 1, wherein further digital signals are also applicable, in addition to limit values, to the inputs as binary signals.

6. The method as claimed in claim 1, wherein at least one output is parameterizable as an inverting output.

7. The method as claimed in claim 1, wherein the characteristic variables include measured values and characteristic variables derived from measured values.

8. The method as claimed in claim 1, wherein the same binary value of a binary signal being respectively assigned to a violation and another binary value of this binary signal being respectively assigned to a non-violation includes a logic one being assigned in the case of a violation and a logic zero being assigned in the case of a non-violation, respectively.

9. The method as claimed in claim 1, wherein the generating of a total binary signal is done in order to indicate to an operator or a further processing system, that characteristic variables have been violated.

10. The method as claimed in claim 1, wherein the characteristic variables include measured values and characteristic variables derived from measured values.

11. The method as claimed in claim 2, wherein the same binary value of a binary signal being respectively assigned to a violation and another binary value of this binary signal being respectively assigned to a non-violation includes a logic one being assigned in the case of a violation and a logic zero being assigned in the case of a non-violation, respectively.

12. The method as claimed in claim 2, wherein the generating of a total binary signal is done in order to indicate to an operator or a further processing system, that characteristic variables have been violated.

13. The method as claimed in claim 2, wherein an output function block generates the total binary signal.

14. The method as claimed in claim 2, wherein each violation is indicated at the corresponding input of the function blocks.

15. The method as claimed in claim 3, wherein each violation is indicated at the corresponding input of the function blocks.

16. A computer readable medium including program segments for, when executed on a computer device, causing the computer device to implement the method of claim 1.
